(19) United States
(12) Patent Application Publication
(10) Pub. No.: US 2024/0081098 A1
(43) Pub. Date: Mar. 7, 2024

(54) THIN FILM TRANSISTOR, ELECTROLUMINESCENT DISPLAY DEVICE AND DRIVING TRANSISTOR

(71) Applicant: LG Display Co., Ltd., Seoul (KR)

(72) Inventors: Younghun Han, Seoul (KR); Jihun Lee, Paju-si (KR)

(21) Appl. No.: 18/240,968

(22) Filed: Aug. 31, 2023

(30) Foreign Application Priority Data
Sep. 2, 2022 (KR) 10-2022-0111629

(51) Int. Cl. H10K 59/121; H10K 59/126

(52) U.S. Cl. CPC H10K 59/1213; H10K 59/126

(57) ABSTRACT

The present disclosure provides a thin film transistor, an electroluminescent display device and a driving transistor. A thin film transistor according to an exemplary embodiment of the present disclosure includes a semiconductor layer, a first insulating layer disposed on the semiconductor layer, two or more first gate electrodes disposed on the first insulating layer and separated from each other, a second insulating layer disposed on the first gate electrodes, a source electrode and a drain electrode disposed on the second insulating layer and respectively electrically connected to a source region and a drain region of the semiconductor layer and a second gate electrode disposed above the first gate electrodes, a channel region may be configured between the source region and the drain region. As a result, it becomes possible to increase subthreshold swing (SS) value, and thus, it becomes possible to improve low gradation spots without increasing a bezel width.

### CROSS-REFERENCE TO RELATED APPLICATION

This application claims the benefit of and priority to Republic of Korea Patent Application No. 10-2022-0111629 filed on Sep. 2, 2022, in the Republic of Korea, which is incorporated by reference in its entirety.

### TECHNICAL FIELD

The present disclosure relates to an electroluminescent display device, and more particularly, to a thin film transistor having a dual-gate structure, an electroluminescent display device and a driving transistor.

### BACKGROUND ART

Recently, as our society advances toward an information-oriented society, the field of display devices for visually expressing an electrical information signal has rapidly advanced. Various display devices having excellent performance in terms of thinness, lightness, and low power consumption, are being developed correspondingly.

Representative display devices include a liquid crystal display (LCD), an organic light emitting display (OLED), and the like.

Among the display devices, an electroluminescent display device including the organic light emitting display, is a self-luminous display device and can be manufactured to be light and thin since it does not require a separate light source, unlike the liquid crystal display having a separate light source. In addition, the electroluminescent display device has advantages in terms of power consumption due to a low voltage driving, and is excellent in terms of a color implementation, a response speed, a viewing angle, and a contrast ratio (CR). Therefore, electroluminescent display devices have been expected to be used in various application fields.

The electroluminescent display device is configured by disposing a light emitting layer formed by using an organic material between two electrodes called an anode and a cathode. Then, when holes from the anode are injected into the light emitting layer and electrons from the cathode are injected into the light emitting layer, the injected electrons and holes recombine with each other to form exciton in the light emitting layer and emit light to display an image.

### SUMMARY

An embodiment of the present disclosure is to provide a thin film transistor having an increase in subthreshold swing SS of a driving transistor and an electroluminescent display device having the same.

Objects of the present disclosure are not limited to the above-mentioned objects, and other objects, which are not mentioned above, can be clearly understood by those skilled in the art from the following descriptions.

A thin film transistor according to an exemplary embodiment of the present disclosure includes a semiconductor layer, a first insulating layer disposed on the semiconductor layer, two or more first gate electrodes disposed on the first insulating layer and separated from each other, a second insulating layer disposed on the first gate electrodes, a source electrode and a drain electrode disposed on the second insulating layer and respectively electrically connected to a source region and a drain region of the semiconductor layer, and a second gate electrode disposed above the first gate electrodes, a channel region may be configured between the source region and the drain region.

An electroluminescent display device according to an exemplary embodiment of the present disclosure includes a first thin film transistor and a second thin film transistor disposed on a substrate and a light emitting element disposed above the first thin film transistor and the second thin film transistor. The first thin film transistor may include a semiconductor layer disposed on the substrate, a gate insulating layer disposed on the semiconductor layer, two or more first gate electrodes disposed on the gate insulating layer and separated from each other, an interlayer insulating layer disposed on the first gate electrodes, a source electrode and a drain electrode disposed on the interlayer insulating layer and respectively electrically connected to a source region and a drain region of the semiconductor layer, and a second gate electrode disposed above the first gate electrodes. The channel region may be configured between the source region and the drain region. The second thin film transistor may include a semiconductor layer disposed on the substrate, the gate insulating layer disposed on the semiconductor layer, a gate electrode disposed on the gate insulating layer, the interlayer insulating layer disposed on the gate electrode, and a source electrode and a drain electrode disposed on the interlayer insulating layer.

A driving transistor according to an exemplary embodiment of the present disclosure comprises: two or more first thin film transistors and a second thin film transistor that are in series with each other, wherein each of the two or more first thin film transistors and the second thin film transistor have a common active region, wherein a first gate electrode of each of the two or more first thin film transistors and a second gate electrode of the second thin film transistor are disposed at the same side of the common active region, and wherein a distance between the second gate electrode of the second thin film transistor and the common active region is greater than a distance between the first gate electrode of each of the two or more first thin film transistors and the common active region.

Other detailed matters of the exemplary embodiments are included in the detailed description and the drawings.

The present disclosure is characterized in that a value of subthreshold swing (SS) is increased through an increase in thickness of a dielectric layer by changing a structure of a driving transistor into a structure of three or more thin film transistors in series. Accordingly, it becomes possible to prevent low gradation spots (or low contrast stain) without increasing a bezel width.

The effects according to the present disclosure are not limited to the contents exemplified above, and more various effects are included in the present specification.

### BRIEF DESCRIPTION OF THE DRAWINGS

FIG. 1 is a schematic configuration diagram of an electroluminescent display device according to an exemplary embodiment of the present disclosure.

FIG. 2 is a circuit diagram of a sub-pixel of the electroluminescent display device of FIG. 1 according to an exemplary embodiment of the present disclosure.

FIG. 3 is a plan view of the electroluminescent display device of FIG. 1 according to an exemplary embodiment of the present disclosure.

FIG. 4 is a cross-sectional view taken along line I-f of FIG. 3 according to an exemplary embodiment of the present disclosure.

FIG. 5 is a cross-sectional view taken along line II-IF of FIG. 3 according to an exemplary embodiment of the present disclosure.

FIG. 6 is a characteristic graph of thin film transistors showing drain current versus gate voltage.

FIGS. 7A to 7F are cross-sectional views sequentially showing parts of a manufacturing process of the thin film transistor of FIG. 4 according to an exemplary embodiment of the present disclosure.

FIG. 8 is a cross-sectional view showing an example of a thin film transistor according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

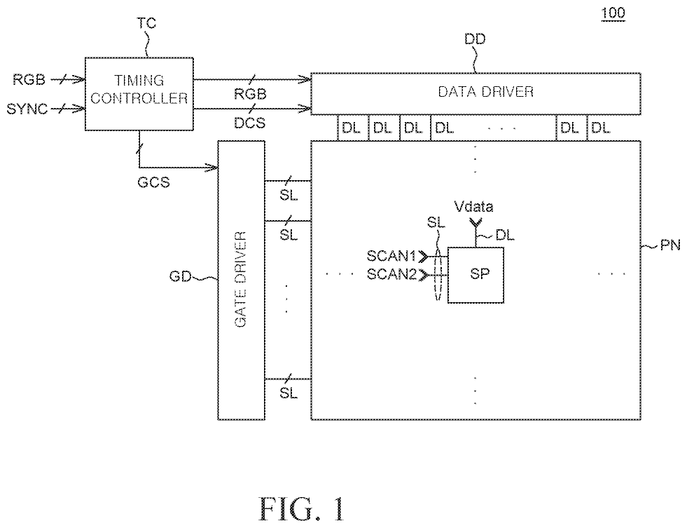

FIG. 1 is a schematic configuration diagram of an electroluminescent display device according to an exemplary embodiment of the present disclosure.

Referring to FIG. 1, an electroluminescent display device 100 according to an exemplary embodiment of the present disclosure may include a display panel PN including a plurality of sub-pixels SP, a gate driver GD and a data driver DD for supplying various signals to the display panel PN, and a timing controller TC for controlling the gate driver GD and the data driver DD.

The gate driver GD may supply a plurality of scan signals to the plurality of scan lines SL according to a plurality of gate control signals GCS provided from the timing controller TC. The plurality of scan signals may include a first scan signal SCAN1 and a second scan signal SCAN2.

The data driver DD may convert image data RGB that is input from the timing controller TC into a data signal Vdata using a reference gamma voltage according to a plurality of data control signals DCS provided from the timing controller TC. Also, the data driver DD may supply the converted data signal Vdata to a plurality of data lines DL.

The timing controller TC aligns image data RGB input from the outside and supplies it to the data driver DD. The timing controller TC may generate the gate control signal GCS and the data control signal DCS using synchronization signals SYNC input from the outside.

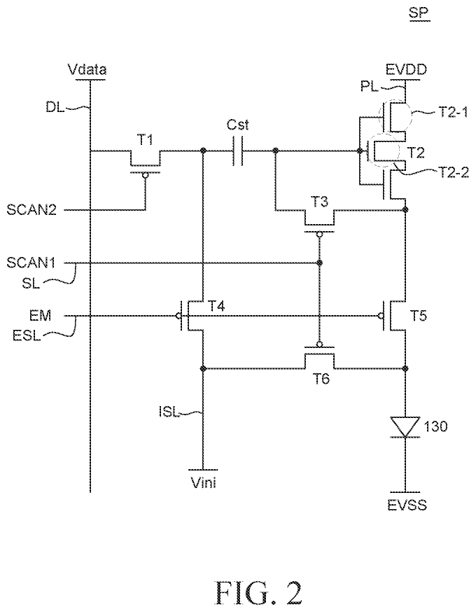

FIG. 2 is a circuit diagram of a sub-pixel of the electroluminescent display device of FIG. 1 according to one embodiment.

Referring to FIG. 2, a pixel circuit of each of the plurality of sub-pixels SP may include a first transistor to a sixth transistor T1, T2, T3, T4, T5, and T6 and a capacitor Cst. Here, although FIG. 2 illustrates a 6T1C structure of the sub-pixel SP including first to sixth transistors T1, T2, T3, T4, T5, and T6 and a capacitor Cst as an example, the present disclosure is not limited to the numbers of the transistors and capacitor.

The first transistor T1 is connected to a second scan line SL and may be controlled by the second scan signal SCAN2 supplied through the second scan line SL. The first transistor T1 may be electrically connected between the data line DL that supplies the data signal Vdata and the capacitor Cst.

A second transistor T2 may be electrically connected between a high potential power line PL to which a high potential power signal EVDD is supplied and a fifth transistor T5. Also, a gate electrode of the second transistor T2 may be electrically connected to the capacitor Cst.

Also, a third transistor T3 may be controlled by the first scan signal SCAN1 supplied through a first scan line SL and compensate for a threshold voltage of the second transistor T2, and the third transistor T3 may be referred to as a compensation transistor.

A fourth transistor T4 may be electrically connected to the capacitor Cst and an initialization signal line ISL to which an initialization signal Vini is supplied. Also, the fourth transistor T4 may be controlled by an emission control signal EM that is supplied through an emission control signal line ESL.

In addition, the fifth transistor T5 is electrically connected between the second transistor T2 and a light emitting element LE and may be controlled by the emission control signal EM that is supplied through the emission control signal line ESL.

The sixth transistor T6 is electrically connected between the initialization signal line ISL to which the initialization signal Vini is supplied and an anode of the light emitting element LE, and the sixth transistor T6 may be controlled by the first scan signal SCAN1 that is supplied through the first scan line SL.

In the above, a case where the pixel circuit of each sub-pixel SP is configured to include the first transistor to the sixth transistor T1, T2, T3, T4, T5, and T6 and the capacitor Cst has been described as an example, but the present disclosure is not limited thereto, as described above.

Meanwhile, the present disclosure is characterized in that the second transistor T2 is configured to have a structure of three or more thin film transistors in series, unlike the other transistors T1, T3, T4, T5, and T6. That is, the second transistor T2 is characterized in that it is configured to have a structure of three or more thin film transistors in series by forming two or more first gate electrodes and one second gate electrode. FIG. 2 exemplifies a case where, between 2-1 transistors T2-1 on two sides according to the first gate electrodes, a 2-2 transistor T2-2 according to the second gate electrode is arranged in series with the 2-1 transistors T2-1. However, the present disclosure is not limited thereto. Further, the present disclosure is characterized in that the 2-2 transistor T2-2 according to the second gate electrode has a greater thickness of a dielectric layer (an insulating layer) interposed between the gate electrode and a semiconductor layer, compared to the 2-1 transistors T2-1 according to the first gate electrodes.

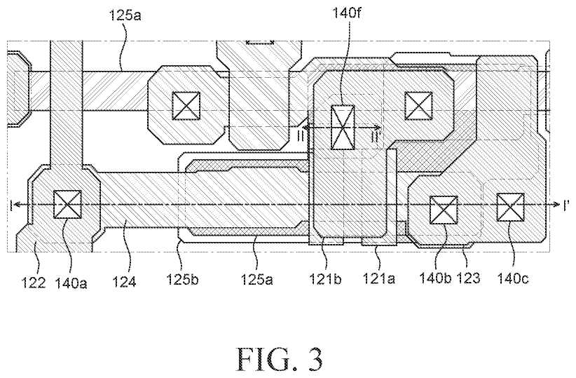

Hereinafter, a pixel structure of the electroluminescent display device according to an exemplary embodiment of the present disclosure will be described in detail with reference to FIGS. 3 to 5.

FIG. 3 is a plan view of the electroluminescent display device of FIG. 1 according to an exemplary embodiment of the present disclosure.

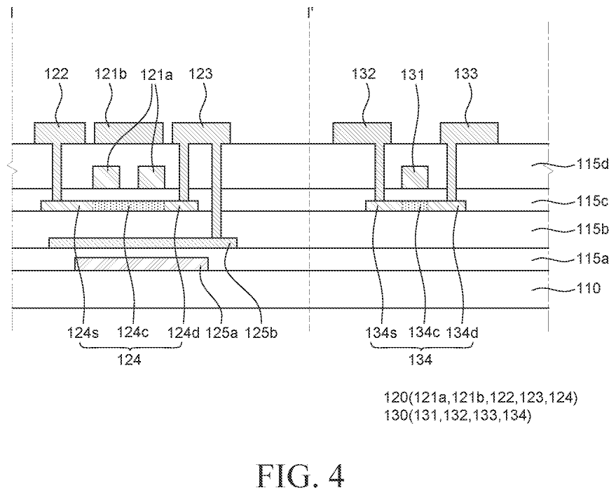

FIG. 4 is a cross-sectional view taken along line I-I′ of FIG. 3 according to an exemplary embodiment of the present disclosure.

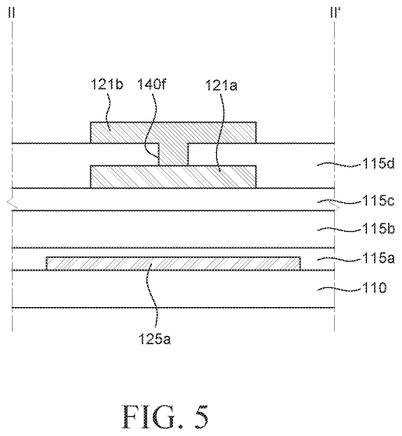

FIG. 5 is a cross-sectional view taken along line II-II′ of FIG. 3 according to an exemplary embodiment of the present disclosure.

FIG. 3 illustrates a part of one sub-pixel.

FIG. 4 illustrates cross-sectional structures of a switching transistor 130 together with a driving transistor 120 taken along line I-I′ of FIG. 3 for convenience of description. That is, a left side of FIG. 4 shows the cross-sectional structure of the driving transistor 120, and a right side of FIG. 4 shows the cross-sectional structure of the switching transistor 130 as an example. However, the present disclosure is not limited thereto, and may include a scan transistor, a sensing transistor, a gate in panel (GIP) transistor, and the like in addition to the switching transistor 130.

For reference, the driving transistor 120 is a thin film transistor that controls a driving current of the light emitting element, and the scan transistor is a thin film transistor that is switched by the scan signal. In addition, the sensing transistor is a thin film transistor that is switched by a sensing signal and may be applied to an external compensation panel, and the GIP transistor is a thin film transistor that replaces a conventional gate driver IC.

In the present disclosure, excellent characteristics of the display panel can be secured by using an oxide thin film transistor having characteristics of high mobility and low off-current. That is, the use of the oxide thin film transistor is advantageous for manufacturing a display panel having a large area as well as in terms of low power consumption, stability, and cost reduction. In particular, when a driving circuit of a non-active area is configured with the oxide thin film transistor in the same manner as an active area, it is advantageous in terms of a reduction in the number of processes and costs. However, the present disclosure is not limited to the oxide thin film transistor.

Meanwhile, a display device according to exemplary embodiments of the present disclosure including the thin film transistor can be implemented as an electronic device such as a smart phone, a mobile phone, a smart watch, a navigation device, a game device, a television (TV), a vehicle head unit, a notebook computer, a laptop computer, a tablet computer, a personal media player (PMP), or a personal digital assistant (PDA). Also, the electronic device may be a flexible device. Hereinafter, an electroluminescent display device will be described as an example of the display device, but the present disclosure is not limited to the electroluminescent display device.

Referring to FIGS. 3 to 5, thin film transistors 120 and 130 may be disposed on a substrate 110.

As described above, the thin film transistors 120 and 130 may include the driving transistor 120 and the switching transistor 130.

The substrate 110 serves to support and protect components of the electroluminescent display device disposed thereon.

Recently, a flexible material having flexible characteristics such as plastic may be used for the flexible substrate 110.

The flexible substrate 110 may be in a form of a film including one of the group consisting of polyester-based polymers, silicone-based polymers, acrylic-based polymers, polyolefin-based polymers, and copolymers thereof.

A first light blocking layer 125a may be disposed on the substrate 110.

The first light blocking layer 125a may be disposed below the driving transistor 120. However, the present disclosure is not limited thereto, and the first light blocking layer may also be disposed below the switching transistor 130.

The first light blocking layer 125a may be formed of a metal material having a light blocking function to block an introduction of external light into a semiconductor layer 124 of the driving transistor 120.

The first light blocking layer 125a may be formed as a single-layer or multilayer structure formed of any one of opaque metals such as aluminum (Al), chromium (Cr), tungsten (W), titanium (Ti), nickel (Ni), neodymium (Nd), molybdenum (Mo), and copper (Cu), or alloys thereof.

A first buffer layer 115a and a second buffer layer 115b may be sequentially disposed on the substrate 110 on which the first light blocking layer 125a is disposed.

The first buffer layer 115a and the second buffer layer 115b may be formed in a structure in which a single insulating layer or a plurality of insulating layers are stacked to block foreign substances including moisture or oxygen introduced from the substrate 110. The first buffer layer 115a and the second buffer layer 115b may be formed of an inorganic insulating material such as silicon oxide (SiOx), silicon nitride (SiNx), or aluminum oxide (AlOx) in a single-layer or multilayer structure. The first buffer layer 115a and the second buffer layer 115b may be eliminated depending on types of thin film transistors.

A second light blocking layer 125b may be disposed on the first buffer layer 115a.

The second light blocking layer 125b may be disposed below the driving transistor 120. However, the present disclosure is not limited thereto, and the second light blocking layer may also be disposed below the switching transistor 130.

The second light blocking layer 125b may be formed of a metal material having a light blocking function to block an introduction of external light into the semiconductor layer 124 of the driving transistor 120.

The second light blocking layer 125b may be formed as a single-layer or multilayer structure formed of any one of opaque metals such as aluminum (Al), chromium (Cr), tungsten (W), titanium (Ti), nickel (Ni), neodymium (Nd), molybdenum (Mo), and copper (Cu), or alloys thereof.

The second buffer layer 115b may be disposed on the second light blocking layer 125b.

In this case, the second buffer layer 115b may be formed in a structure in which a single insulating layer or a plurality of insulating layers are stacked to block foreign substances including moisture or oxygen introduced from the substrate 110. The second buffer layer 115b may be formed of an inorganic insulating material such as silicon oxide, silicon nitride, or aluminum oxide, which is in a single-layer or multilayer structure. The second buffer layer 115b may be eliminated depending on types of thin film transistors. For example, the second buffer layer 115b is formed of silicon oxide, but the present disclosure is not limited thereto.

The thin film transistors 120 and 130 may be disposed on the second buffer layer 115b.

As described above, the thin film transistor on the left side of FIG. 4 can be the driving transistor 120, and the thin film transistor on the right side of FIG. 4 can be the switching transistor 130. However, the present disclosure is not limited thereto, and a sensing transistor and a compensation circuit may also be included in the electroluminescent display device.

The switching transistor 130 may be turned on by a gate pulse that is supplied to a gate line and transmit a data voltage that is supplied through the data line to gate electrodes 121a and 121b of the driving transistor 120.

The driving transistor 120 may transfer a current transmitted through a power line to the anode according to a signal received from the switching transistor 130 and control light emission by the current transmitted to the anode.

The driving transistor 120 may include a first gate electrode 121a and a second gate electrode 121b, the semiconductor layer 124, a source electrode 122 and a drain electrode 123.

The switching transistor 130 may include a gate electrode 131, a semiconductor layer 134, a source electrode 132, and a drain electrode 133.

The semiconductor layers 124 and 134 may be formed of an oxide semiconductor. By using an oxide thin film transistor having high mobility and low off-current characteristics, excellent characteristics of the display panel can be secured. In particular, when a driver thin film transistor of a gate in panel (GIP) area is formed of an oxide thin film transistor in the same manner as the active area, there are advantages in that the number of processes and costs are reduced. However, the semiconductor layers 124 and 134 according to the present disclosure are not limited to the oxide semiconductor.

The oxide semiconductor has excellent mobility and uniformity properties. In this case, the oxide semiconductor may be formed of a quaternary metal oxide such as an indium tin gallium zinc oxide (InSnGaZnO)-based material, a ternary metal oxide such as an indium gallium zinc oxide (InGaZnO)-based material, an indium tin zinc oxide (InSnZnO)-based material, an indium aluminum zinc oxide (InAlZnO)-based material, a tin gallium zinc oxide (SnGaZnO)-based material, an aluminum gallium zinc oxide (AlGaZnO)-based material, and a tin aluminum zinc oxide (SnAlZnO)-based material, a binary metal oxide such as an indium zinc oxide (InZnO)-based material, a tin zinc oxide (SnZnO)-based material, an aluminum zinc oxide (AlZnO)-based material, a zinc magnesium oxide (ZnMgO)-based material, a tin magnesium oxide (SnMgO)-based material, an indium magnesium oxide (InMgO)-based material, an indium oxide (InO)-based material, a tin oxide (SnO)-based material, an indium gallium oxide (InGaO)-based material, a zinc oxide (ZnO)-based material or the like. Composition ratios of the respective elements are not limited.

The semiconductor layers 124 and 134 may include source regions 124s and 134s and drain regions 124d and 134d containing p-type impurities or n-type impurities, and channel regions 124c and 134c between the source regions 124s and 134s and the drain regions 124d and 134d. The semiconductor layers 124 and 134 may further include a low concentration-doped region between the source regions 124s and 134s and drain regions 124d and 134d that are adjacent to the channel regions 124c and 134c, but the present disclosure is not limited thereto.

The source regions 124s and 134s and the drain regions 124d and 134d are regions doped with impurities at a high concentration, and may be connected to the source electrodes 122 and 132 and the drain electrodes 123 and 133 of the thin film transistors 120 and 130, respectively.

As the impurity ion, the p-type impurity or n-type impurity may be used. The p-type impurity may be one of boron (B), aluminum (Al), gallium (Ga), and indium (In), and the n-type impurity may be one of phosphorus (P), arsenic (As), and antimony (Sb), but the present disclosure is not limited thereto.

The channel regions 124c and 134c may be doped with n-type impurities or p-type impurities according to a thin film transistor structure of the N-MOS or P-MOS.

A gate insulating layer 115c may be disposed on the semiconductor layers 124 and 134.

The gate insulating layer 115c is composed of a single layer of silicon oxide (SiOx) or silicon nitride (SiNx) or multiple layers thereof, and may be disposed between the first and second gate electrodes 121a and 121b and the semiconductor layer 124 so that a current flowing through the semiconductor layer 124 of the driving transistor 120 does not flow into the first and second gate electrodes 121a and 121b. In addition, the gate insulating layer 115c may be disposed between the gate electrode 131 and the semiconductor layer 134 so that a current flowing through the semiconductor layer 134 of the switching transistor 130 does not flow into the gate electrode 131. The silicon oxide is less ductile than metal, but is superior in ductility to silicon nitride, and may be formed as a single layer or multiple layers depending on characteristics thereof.

The gate electrodes 121a, 121b, and 131 may be composed of a single layer or multiple layers formed of conductive metals such as copper (Cu), aluminum (Al), chromium (Cr), molybdenum (Mo), gold (Au), titanium (Ti), nickel (Ni), and neodymium. (Nd), or an alloy thereof, but the present disclosure is not limited thereto.

The source electrodes 122 and 132 and the drain electrodes 123 and 133 may be composed of a single layer or multiple layers formed of conductive metals such as copper (Cu), aluminum (Al), chromium (Cr), molybdenum (Mo), gold (Au), titanium (Ti), nickel (Ni), and neodymium. (Nd), or an alloy thereof, but the present disclosure is not limited thereto.

An interlayer insulating layer 115d may be disposed between the gate electrodes 121a, 121b, and 131 and the source electrodes 122 and 132 and the drain electrodes 123 and 133. Here, the interlayer insulating layer 115d may be formed of a single layer of silicon oxide (SiOx) or silicon nitride (SiNx) or multiple layers thereof.

In this case, the source electrode 122 of the driving transistor 120 may be electrically connected to the source region 124s of the semiconductor layer 124 through a first contact hole 140a, and the drain electrode 123 of the driving transistor 120 may be electrically connected to the drain region 124d of the semiconductor layer 124 through a second contact hole 140b. In addition, the drain electrode 123 of the driving transistor 120 may be electrically connected to the second light blocking layer 125b through a third contact hole 140c.

Also, the source electrode 132 of the switching transistor 130 may be electrically connected to the source region 134s of the semiconductor layer 134 through a fourth contact hole, and the drain electrode 133 thereof may be electrically connected to the drain region 134d of the semiconductor layer 134 through a fifth contact hole.

Meanwhile, the driving transistor 120 according to an exemplary embodiment of the present disclosure is characterized in that it has a structure of three thin film transistors in series, having dielectric layers of different thicknesses, in other words, specifically, it has two 2-1 transistors having the same thickness and one 2-2 transistor having a thickness different from that of the 2-1 transistors. That is, it is characterized in that an existing thin film transistor is changed into a structure of three thin film transistors in series having dielectric layers of different thicknesses. However, the present disclosure is not limited thereto, and the driving transistor of the present disclosure may have a structure of four or more thin film transistors in series, having dielectric layers of different thicknesses.

To this end, an exemplary embodiment of the present disclosure is characterized by including two first gate electrodes 121a located on an existing gate electrode layer and one second gate electrode 121b located on the same layer as the source electrode 122 and the drain electrode 123.

The two first gate electrodes 121a are spaced apart from each other by a predetermined distance (interval), and the second gate electrode 121b may be disposed above the first gate electrodes 121a to cover the predetermined distance.

In this case, it is characterized in that the semiconductor layer 124 outside the first gate electrodes 121a constitutes the source region 124s and the drain region 124d, and the semiconductor layer 124 below the first gate electrodes 121a and the second gate electrode 121b constitutes the channel region 124c. Also, it is characterized in that an edge of one first gate electrode 121a and a boundary between the source region 124s and the channel region 124c may be self-aligned, and an edge of another first gate electrode 121a and a boundary between the drain region 124d and the channel region 124c may be self-aligned.

The second gate electrode 121b may overlap at least a portion of the first gate electrodes 121a, but is not limited thereto. The second gate electrode 121b may be disposed between the source electrode 122 and the drain electrode 123.

The second gate electrode 121b may be electrically connected to the first gate electrodes 121a through a sixth contact hole 140f.

As the second gate electrode 121b is positioned on a layer on which the source electrode 122 and the drain electrode 123 are located, the second gate electrode 121b is disposed at a relatively far distance from the channel region 124c compared to the first gate electrode 121a. That is, only one dielectric layer, that is, only the gate insulating layer 115c is disposed (interposed) between the first gate electrode 121a and the channel region 124c, whereas two dielectric layers, that is, the gate insulating layer 115c and the interlayer insulating layer 115d may be disposed (interposed) between the second gate electrode 121b and the channel region 124c. Therefore, a structure of three thin film transistors in series that have dielectric layers of different thicknesses can be configured. In addition, a thickness of the dielectric layers between the second gate electrode 121b and the channel region 124c is greater than an existing case, so that a decrease in capacitance is caused and thus, subthreshold swing SS may increase. In particular, since only the gate insulating layer 115c can be applied as a dielectric layer in transistors other than the driving transistor 120, low gradation spots can be prevented by using the gate insulating layer 115c having the same thickness as an existing one, without an increase in a bezel width.

For reference, subthreshold swing SS can be interpreted as an increase amount of a gate voltage which is required to increase a current by 10 times in one embodiment. That is, as the subthreshold swing SS decreases, even if the gate voltage is raised a little, it means that the amount of the current increases exponentially rapidly, and an element can be turned on/off more rapidly.

That is, one of issues of the current display devices is spots expressed in a low gradation. The cause of spots expressed in a low gradation can be considered as a large difference in current in a subthreshold region of the driving transistor. It is not easy to control the corresponding region with compensation because a variation in drain current according to the gate voltage is large. That is, low gradation spots may occur due to low SS of the driving transistor. For an increase of the subthreshold swing SS, when a thickness of the buffer layer is reduced to increase capacitance between the semiconductor layer and the light blocking layer, disconnection between the semiconductor layer and the light blocking layer may be problematic. In addition, for an increase of SS, when a thickness of the gate insulating layer is increased to reduce capacitance between the semiconductor layer and the gate electrode in order to increase the subthreshold swing SS, the bezel width can be increased due to a decrease in GIP driving current. That is, when the thickness of the gate insulating layer of the driving transistor is increased, the thickness of the gate insulating layer of the GIP transistor is also increased, so that the GIP driving current is reduced and the bezel width is increased.

Accordingly, the present disclosure is characterized in that only the subthreshold swing SS of the driving transistor 120 is increased without loss of the GIP driving current through a structure change of the driving transistor 120. That is, the present disclosure is characterized in that the driving transistor 120 is changed to a structure of three or more thin film transistors in series having dielectric layers of different thicknesses. Accordingly, the 2-1 transistors (T2-1 in FIG. 2) on two sides according to the first gate electrodes 121a may employ the existing gate insulating layer 115c, that is, for example, the gate insulating layer 115c having a thickness of about 1500 Å, and the 2-2 transistor (T2-2 in FIG. 2) according to the second gate electrode 121b between the 2-1 transistors T2-1 on two sides may further employ the interlayer insulating layer 115d having a thickness of, for example, about 2000 to 3000 Å, in addition to the gate insulating layer 115c having a thickness of about 1500 Å.

Accordingly, in the case of the 2-2 transistor T2-2, capacitance between the second gate electrode 121b and the channel region 124c is reduced to result in a decrease in gate modulation capability, so that SS of the driving transistor 120 increases.

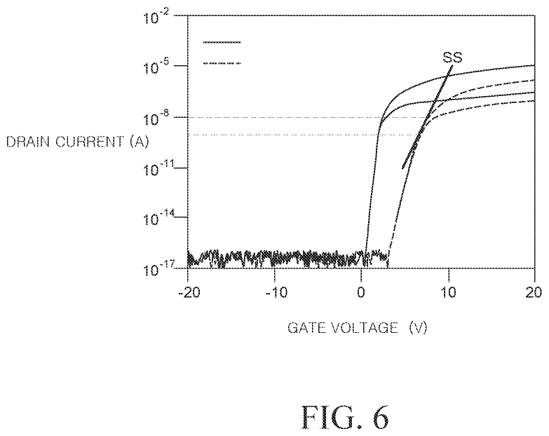

FIG. 6 is a characteristic graph of thin film transistors showing drain current versus gate voltage.

A solid line in FIG. 6 shows transfer characteristics of a driving transistor of Comparative Example, and a dotted line in FIG. 6 shows transfer characteristics of the diving transistor according to an exemplary embodiment of the present disclosure as an example. That is, the solid line in FIG. 6 shows the transfer characteristics of an existing driving transistor having dielectric layers of a single thickness, and the dotted line in FIG. 6 shows the transfer characteristics of the driving transistor having dielectric layers of two different thicknesses according to an exemplary embodiment of the present disclosure.

Referring to FIG. 6, it can be seen that a transfer curve of the driving transistor of an exemplary embodiment of the present disclosure is gentler below a threshold voltage compared to Comparative Example. That is, it can be seen that subthreshold swing SS of Comparative Example is 0.25, whereas subthreshold swing SS of an exemplary embodiment of the present disclosure is 0.60, which is an increase of about 140%.

For reference, the subthreshold swing SS can be interpreted as an increase amount of a gate voltage which is required to increase a current by 10 times. That is, as the subthreshold swing SS decreases, even if the gate voltage is raised a little, it means that the amount of the current increases exponentially rapidly, and an element can be turned on/off more rapidly.

For example, the subthreshold swing SS can be considered as a reciprocal of a slope of the transfer curve in a range of 1 nA, that is, 1×10⁻⁹ A to 10 nA, that is, 1×10⁻⁸ A in the transfer curve of FIG. 6. For reference, in FIG. 6, only SS of the driving transistor according to an exemplary embodiment of the present disclosure is illustrated, but it may be applied to the driving transistor according to Comparative Example in the same manner.

As described above, according to an exemplary embodiment of the present disclosure, the subthreshold swing SS can be increased by selectively increasing the thickness of the dielectric layer of the driving transistor without degradation in GIP driving capability. Accordingly, it is possible to prevent low gradation spots without process issues such as disconnection of the semiconductor layer and an increase in the bezel width.

Meanwhile, the present disclosure is characterized in that, after forming a first gate electrode pattern, a semiconductor layer is ion-doped to form a source region and a drain region, and the first gate electrode pattern is patterned to form a plurality of first gate electrodes. In this case, the present disclosure is characterized in that, by using the first gate electrode pattern as a mask during ion doping of the semiconductor layer, so that self-alignment is allowed in which a length of a channel matches a width of the first gate electrode pattern. In addition, the present disclosure is characterized in that a second gate electrode is formed above the plurality of first gate electrodes when the source electrode and the drain electrode are formed after the first gate electrodes are formed. This will be described in detail through a manufacturing process of the present disclosure below.

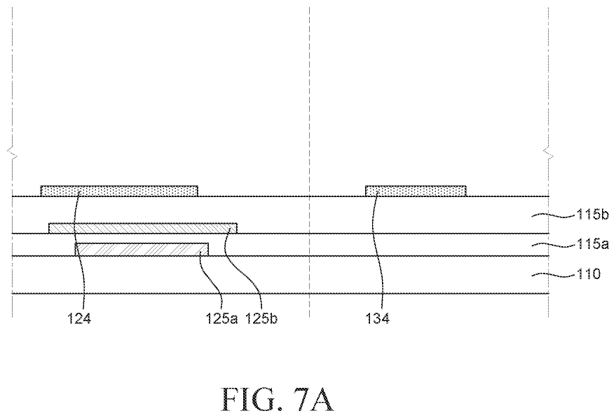

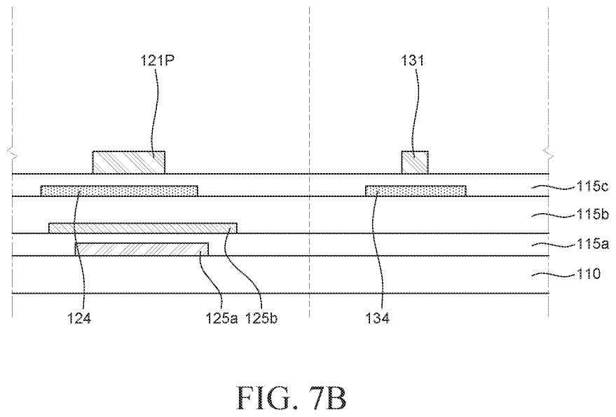

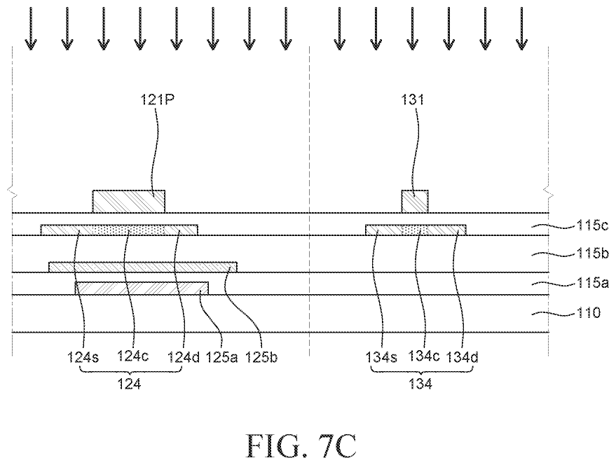

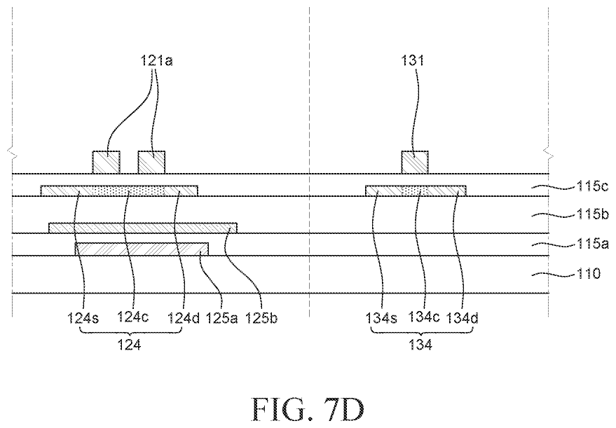

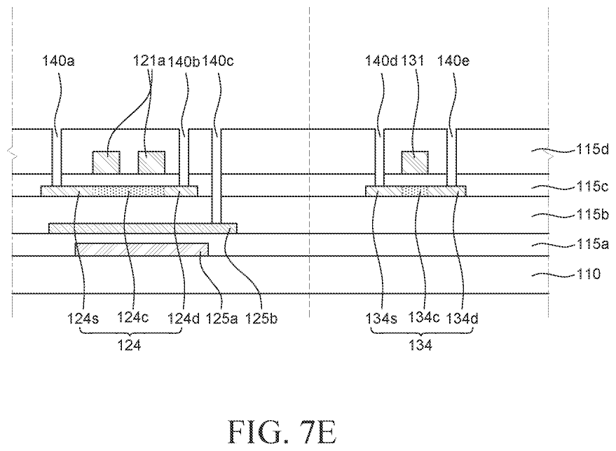

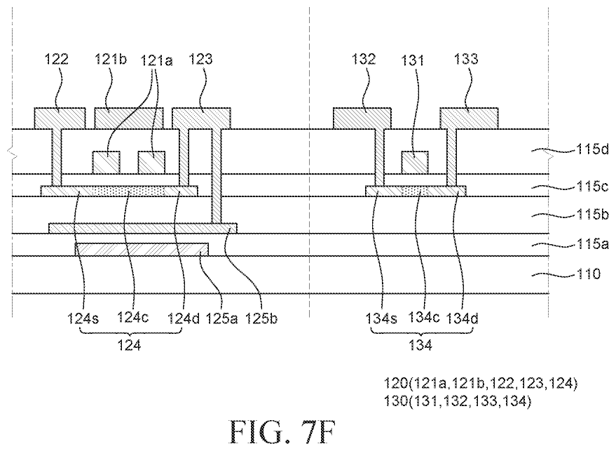

FIGS. 7A to 7F are cross-sectional views sequentially showing parts of a manufacturing process of the thin film transistor of FIG. 4 according to one embodiment.

FIGS. 7A to 7F are cross-sectional views illustrating a manufacturing process of the driving transistor and the switching transistor as an example. Left sides of FIGS. 7A to 7F sequentially show the manufacturing process of the driving transistor, and the right sides of FIGS. 7A to 7F sequentially show the manufacturing process of the switching transistor.

Referring to FIG. 7A, the first light blocking layer 125a may be formed on the substrate 110.

Recently, a flexible material having flexible characteristics such as plastic can be used for the flexible substrate 110.

The flexible substrate 110 may be in the form of a film including one of the group consisting of polyester-based polymers, silicone-based polymers, acrylic-based polymers, polyolefin-based polymers, and copolymers thereof.

The first light blocking layer 125a may be disposed below the driving transistor. However, the present disclosure is not limited thereto, and the first light blocking layer may also be disposed below the switching transistor.

The first light blocking layer 125a may be formed as a single-layer or multilayer structure formed of any one of opaque metals such as aluminum (Al), chromium (Cr), tungsten (W), titanium (Ti), nickel (Ni), neodymium (Nd), molybdenum (Mo), and copper (Cu), or alloys thereof.

Next, the first buffer layer 115a may be formed on the substrate 110 on which the first light blocking layer 125a is formed. The first buffer layer 115a may be formed of an inorganic insulating material such as silicon oxide (SiOx), silicon nitride (SiNx), or aluminum oxide (AlOx) in a single-layer or multilayer structure.

Next, the second light blocking layer 125b may be formed on the first buffer layer 115a.

The second light blocking layer 125b may be disposed below the driving transistor. However, the present disclosure is not limited thereto, and the second light blocking layer may be disposed below the switching transistor.

The second light blocking layer 125b may be formed as a single-layer or multilayer structure formed of any one of opaque metals such as aluminum (Al), chromium (Cr), tungsten (W), titanium (Ti), nickel (Ni), neodymium (Nd), molybdenum (Mo), and copper (Cu), or alloys thereof.

The second light blocking layer 125b may be formed to overlap a portion of the first light blocking layer 125a.

Next, the second buffer layer 115b may be formed on the second light blocking layer 125b.

The second buffer layer 115b may be formed of an inorganic insulating material such as silicon oxide, silicon nitride, or aluminum oxide in a single-layer or multilayer structure.

Next, the semiconductor layers 124 and 134 may be formed on the second buffer layer 115b.

The semiconductor layers 124 and 134 may be formed of an oxide semiconductor, but are not limited thereto, and may be formed of amorphous silicon or polycrystalline silicon.

The semiconductor layers 124 and 134 may include a driving transistor semiconductor layer 124 and a switching transistor semiconductor layer 134.

The driving transistor semiconductor layer 124 may be formed to overlap a portion of the second light blocking layer 125b.

Next, referring to FIG. 7B, the gate insulating layer 115c may be formed on the semiconductor layers 124 and 134.

The gate insulating layer 115c may be formed of a single layer of silicon oxide (SiOx) or silicon nitride (SiNx) or multiple layers thereof.

Next, a first gate electrode pattern 121P may be formed above the driving transistor semiconductor layer 124 on the gate insulating layer 115c, and at the same time, the gate electrode 131 is formed above the switching transistor semiconductor layer 134.

The first gate electrode pattern 121P may be formed to overlap a central portion of the driving transistor semiconductor layer 124.

The first gate electrode pattern 121P and the gate electrode 131 may be formed as a single layer or multiple layers formed of conductive metals such as copper (Cu), aluminum (Al), chromium (Cr), molybdenum (Mo), gold (Au), titanium (Ti), nickel (Ni), and neodymium (Nd), or an alloy thereof, but the present disclosure is not limited thereto.

Next, referring to FIG. 7C, ions are implanted into predetermined regions of the semiconductor layers 124 and 134 using the first gate electrode pattern 121P and the gate electrode 131 as masks to thereby form the source regions 124s and 134s and drain regions 124d and 134d.

As the impurity ion, the p-type impurity or n-type impurity may be used. The p-type impurity may be one of boron (B), aluminum (Al), gallium (Ga), and indium (In), and the n-type impurity may be one of phosphorus (P), arsenic (As), and antimony (Sb), but the present disclosure is not limited thereto.

In this case, the source regions 124s and 134s and the drain regions 124d and 134d are regions into which impurities are implanted at a high concentration, and the channel regions 124c and 134c in which ions are not implanted may be formed between the source regions 124s and 134s and the drain regions 124d and 134d.

A low concentration-doped region may be further included between the source regions 124s and 134s and drain regions 124d and 134d that are adjacent to the channel regions 124c and 134c, but the present disclosure is not limited thereto.

In this case, the driving transistor semiconductor layer 124 outside the first gate electrode pattern 121P constitutes the source region 124s and the drain region 124d of the driving transistor, and the switching transistor semiconductor layer 134 outside the gate electrode 131 may constitute the source region 134s and the drain region 134d of the switching transistor.

That is, one outer edge of the first gate electrode pattern 121P and a boundary between the source region 124s and the channel region 124c of the driving transistor may be self-aligned, and the other outer edge of the gate electrode 131 and a boundary between the drain region 124d and the channel region 124c of the driving transistor may be self-aligned. In addition, one outer edge of the gate electrode 131 and a boundary between the source region 134s and the channel region 134c of the switching transistor may be self-aligned, and the outer edge of the gate electrode 131 and the drain region 134d and the channel region 134c of the switching transistor may be self-aligned.

Next, referring to FIG. 7D, a plurality of the first gate electrodes 121a may be formed by patterning the first gate electrode pattern 121P.

FIG. 7D illustrates a case in which two first gate electrodes 121a are formed by removing a portion of a central portion of the first gate electrode pattern 121P as an example, but the present disclosure is not limited thereto. Three or more first gate electrodes 121a may be formed by removing portions of the first gate electrode pattern 121P except for both edges of the first gate electrode pattern 121P.

Accordingly, the gate insulating layer 115c may be exposed between the two first gate electrodes 121a, and the channel region 124c of the driving transistor semiconductor layer 124 may be positioned below the exposed gate insulating layer 115c.

The two first gate electrodes 121a may be separated from each other by a predetermined distance (interval).

Next, referring to FIG. 7E, the interlayer insulating layer 115d may be formed on the first gate electrode 121a and the gate electrode 131.

The interlayer insulating layer 115d may be formed of a single layer of silicon oxide (SiOx) or silicon nitride (SiNx) or multiple layers thereof, and may be formed to have a thickness greater than that of the gate insulating layer 115c.

Next, the gate insulating layer 115c and the interlayer insulating layer 115d may be selectively removed to form the first contact hole 140a exposing the source region 124s of the driving transistor semiconductor layer 124 and the second contact hole 140b exposing the drain region 124d of the driving transistor semiconductor layer 124. In addition, the third contact hole 140c exposing the second light blocking layer 125b may be formed by selectively removing the second buffer layer 115b, the gate insulating layer 115c, and the interlayer insulating layer 115d.

In addition, the gate insulating layer 115c and the interlayer insulating layer 115d may be selectively removed to form a fourth contact hole 140d exposing the source region 134s of the switching transistor semiconductor layer 134 and a fifth contact hole 140e exposing the drain region 134d of the switching transistor semiconductor layer 134.

Next, referring to FIG. 7F, the source electrodes 122 and 132, the drain electrodes 123 and 133, and the second gate electrode 121b may be formed on the interlayer insulating layer 115d.

The source electrodes 122 and 132, the drain electrodes 123 and 133, and the second gate electrode 121b may be formed as single layers or multiple layers formed of conductive metals such as copper (Cu), aluminum (Al), chromium (Cr), molybdenum (Mo), gold (Au), titanium (Ti), nickel (Ni), and neodymium (Nd), or an alloy thereof, but the present disclosure is not limited thereto.

In this case, the source electrode 122 of the driving transistor may be electrically connected to the source region 124s of the driving transistor semiconductor layer 124 through the first contact hole 140a. In addition, the drain electrode 123 of the driving transistor may be electrically connected to the drain region 124d of the driving transistor semiconductor layer 124 through the second contact hole 140b, while the drain electrode 123 of the driving transistor may be electrically connected to the second light blocking layer 125b through the third contact hole 140c.

Also, the source electrode 132 of the switching transistor may be electrically connected to the source region 134s of the switching transistor semiconductor layer 134 through the fourth contact hole 140d, and the drain electrode 133 of the switching transistor may be electrically connected to the drain region 134d of the switching transistor semiconductor layer 134 through the fifth contact hole 140e.

The second gate electrode 121b may be disposed above the first gate electrodes 121a to cover the predetermined distance between the two first gate electrodes 121a.

In this case, the driving transistor semiconductor layer 124 outside the first gate electrode 121a constitutes the source region 124s and the drain region 124d, and the driving transistor semiconductor layer 124 below the first gate electrodes 121a and the second gate electrode 121b constitute the channel region 124c. An outer edge of one first gate electrode 121a and a boundary between the source region 124s and the channel region 124c of the driving transistor semiconductor layer 124 may be self-aligned, and an outer edge of another first gate electrode 121a and a boundary between the drain region 124d and the channel region 124c of the driving transistor semiconductor layer 124 may be self-aligned.

The second gate electrode 121b may overlap at least a portion of the first gate electrodes 121a, but is not limited thereto. The second gate electrode 121b may be disposed between the source electrode 122 and the drain electrode 123.

The second gate electrode 121b may be electrically connected to the first gate electrodes 121a through the sixth contact hole.

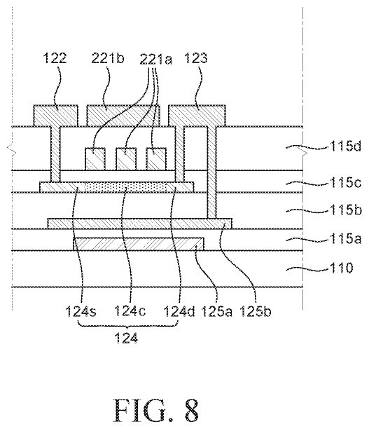

Meanwhile, the driving transistor of the present disclosure is characterized in that it has a structure of three or more thin film transistors in series, and a case of having a structure of four thin film transistors in series will be described in detail with reference to FIG. 8.

FIG. 8 is a cross-sectional view showing an example of a thin film transistor according to another exemplary embodiment of the present disclosure.

Since other configurations of the embodiment of FIG. 8 are substantially identical to those of the aforementioned embodiment of FIGS. 3 to 5 with only a difference in configuration of three first gate electrodes 221a, so duplicate descriptions will be omitted. The same reference numerals will be used for the same components.

In FIG. 8, only a cross-sectional structure of a driving transistor is shown for convenience of description, and a switching transistor, a scan transistor, a sensing transistor, and a GIP transistor are substantially the same as those of the aforementioned embodiment.

Referring to FIG. 8, the first light blocking layer 125a may be disposed on the substrate 110.

The first light blocking layer 125a may be disposed below the driving transistor.

The first buffer layer 115a and the second buffer layer 115b may be sequentially disposed on the substrate 110 on which the first light blocking layer 125a is disposed. The second light blocking layer 125b may be disposed on the first buffer layer 115a.

The second light blocking layer 125b may be disposed below the driving transistor.

The second buffer layer 115b may be disposed on the second light blocking layer 125b.

The driving transistor may be disposed on the second buffer layer 115b.

The driving transistor may include a first gate electrode 221a and a second gate electrode 221b, the semiconductor layer 124, the source electrode 122, and the drain electrode 123.

The semiconductor layer 124 may include the source region 124s and the drain region 124d containing p-type impurities or n-type impurities, and the channel region 124c between the source region 124s and the drain region 124d. A low concentration-doped region may be further included between the source region 124s and drain region 124d adjacent to the channel region 124c, but the present disclosure is not limited thereto.

The source region 124s and the drain region 124d are regions doped with impurities at a high concentration, and may be connected to the source electrode 122 and the drain electrode 123 of the driving transistor, respectively.

The gate insulating layer 115c may be disposed on the semiconductor layer 124.

The interlayer insulating layer 115d may be disposed between the gate electrodes 221a and 221b, and the source electrode 122 and drain electrode 123.

The source electrode 122 of the driving transistor may be electrically connected to the source region 124s of the semiconductor layer 124 through a first contact hole, and the drain electrode 123 of the driving transistor may be connected to the drain region 124d of the semiconductor layer 124 through a second contact hole. In addition, the drain electrode 123 of the driving transistor may be electrically connected to the second light blocking layer 125b through a third contact hole.

Meanwhile, the driving transistor according to another exemplary embodiment of the present disclosure is characterized by having a structure of four thin film transistors in series, having dielectric layers having different thicknesses.

To this end, another exemplary embodiment of the present disclosure is characterized by including three first gate electrodes 221a located on an existing gate electrode layer and one second gate electrode 221b located on a layer on which the source electrode 122 and drain electrode 123 are positioned.

The three first gate electrodes 221a are spaced apart from each other by a predetermined distance (interval), and the second gate electrode 221b may be disposed above the first gate electrodes 221a to cover the predetermined distance.

In this case, the semiconductor layer 124 outside the first gate electrodes 221a constitutes the source region 124s and the drain region 124d, and the semiconductor layer 124 below the first gate electrodes 221a and the second gate electrode 221b constitutes the channel region 124c. In addition, an outer edge of one first gate electrode 221a and a boundary between the source region 124s and the channel region 124c may be self-aligned, and an outer edge of another first gate electrode 221a and a boundary between the drain region 124d and the channel region 124c may be self-aligned.

The second gate electrode 221b may overlap at least a portion of the first gate electrodes 221a, but is not limited thereto. The second gate electrode 221b may be disposed between the source electrode 122 and the drain electrode 123.

As described above, the second gate electrode 221b may be electrically connected to the first gate electrode 221a through a sixth contact hole.

Meanwhile, when the display device is an electroluminescent display device, a light emitting element including an anode, a light emitting unit, and a cathode may be disposed above the thin film transistor.

The light emitting unit serves to emit light and may include at least one layer among a hole injection layer (HIL), a hole transport layer (HTL), a light emitting layer, an electron transport layer (ETL), and an electron injection layer (EIL). Some of the components of the light emitting unit may be omitted depending on a structure or characteristics of the electroluminescent display device. Here, as the light emitting layer, it is also possible to apply an electroluminescent layer and an inorganic light emitting layer.

In addition, an encapsulation layer may be disposed on the light emitting element.

Specifically describing the encapsulation layer, a primary protective layer, an organic layer, and a secondary protective layer may be sequentially formed on an upper surface of the substrate 110 on which the light emitting element is formed to form the encapsulation layer serving as an encapsulation unit. However, the number of inorganic layers and organic layers constituting the encapsulation layer is not limited thereto.

In the case of the first protective layer, since it is formed of an inorganic insulating layer, stack coverage is not good due to a lower step. However, since the organic layer serves as a planarization unit, the second protective layer is not affected by the step due to an underlying layer. In addition, since a thickness of the organic layer formed of a polymer is sufficiently thick, cracks caused by a foreign material can be compensated for, and it can be referred to as a foreign material prevention layer.

For encapsulation, a multilayered protective film may be positioned to face a front surface of the substrate 110 including the secondary protective layer, and a transparent adhesive having adhesive properties may be interposed between the encapsulation layer and the protective layer.

A polarizing plate for preventing reflection of light incident from the outside may be attached on the protective film, but the present disclosure is not limited thereto.

The exemplary embodiments of the present disclosure can also be described as follows:

According to an aspect of the present disclosure, there is provided a thin film transistor. The thin film transistor comprises a semiconductor layer, a first insulating layer disposed on the semiconductor layer, two or more first gate electrodes disposed on the first insulating layer and separated from each other, a second insulating layer disposed on the first gate electrodes, a source electrode and a drain electrode disposed on the second insulating layer and respectively electrically connected to a source region and a drain region of the semiconductor layer and a second gate electrode disposed above the first gate electrodes, a channel region may be configured between the source region and the drain region.

The second gate electrode may be disposed on the second insulating layer between the source electrode and the drain electrode.

The two or more separated first gate electrodes may be spaced apart from each other by a predetermined distance, and the second gate electrode may be disposed above the first gate electrodes to cover the predetermined distance.

The semiconductor layer outside the first gate electrodes may constitute the source region and the drain region, and the semiconductor layer below the first gate electrodes and the second gate electrode may constitute the channel region.

An outer edge of one first gate electrode and a boundary between the source region and the channel region may be self-aligned and an outer edge of another first gate electrode and a boundary between the drain region and the channel region may be self-aligned.

The second gate electrode may overlap at least a portion of the first gate electrodes.

The second gate electrode may be electrically connected to the first gate electrodes through a contact hole.

The second insulating layer may have a thickness greater than a thickness of the first insulating layer.

According to an aspect of the present disclosure, there is provided an electroluminescent display device. The electroluminescent display device comprises a first thin film transistor and a second thin film transistor disposed on a substrate and a light emitting element disposed above the first thin film transistor and the second thin film transistor, wherein the first thin film transistor includes, a semiconductor layer disposed on the substrate, a gate insulating layer disposed on the semiconductor layer, two or more first gate electrodes disposed on the gate insulating layer and separated from each other, an interlayer insulating layer disposed on the first gate electrodes, a source electrode and a drain electrode disposed on the interlayer insulating layer and respectively electrically connected to a source region and a drain region of the semiconductor layer, and a second gate electrode disposed above the first gate electrodes, wherein a channel region is configured between the source region and the drain region, and wherein the second thin film transistor includes, a semiconductor layer disposed on the substrate, the gate insulating layer disposed on the semiconductor layer, a gate electrode disposed on the gate insulating layer, the interlayer insulating layer disposed on the gate electrode, and a source electrode and a drain electrode disposed on the interlayer insulating layer.

The electroluminescent display device may further include a first light blocking layer disposed on the substrate, a first buffer layer disposed on the first light blocking layer, a second light blocking layer disposed on the first buffer layer and a second buffer layer disposed on the second light blocking layer.

The first light blocking layer and the second light blocking layer may be disposed under the first thin film transistor.

The second gate electrode may be disposed on the interlayer insulating layer between the source electrode and the drain electrode of the first thin film transistor.

The two or more separated first gate electrodes may be spaced apart from each other by a predetermined distance, and the second gate electrode may be disposed above the first gate electrodes to cover the predetermined distance.

The second gate electrode may overlap at least a portion of the first gate electrodes.

The second gate electrode may be electrically connected to the first gate electrodes through a contact hole.

The interlayer insulating layer may have a thickness greater than a thickness of the gate insulating layer.

The first thin film transistor may include a driving transistor.

The second thin film transistor may include a switching transistor, a scan transistor, a sensing transistor, and a gate in panel (GIP) transistor.

According to an aspect of the present disclosure, there is provided a driving transistor. The driving transistor comprises: two or more first thin film transistors and a second thin film transistor that are in series with each other, wherein each of the two or more first thin film transistors and the second thin film transistor have a common active region, wherein a first gate electrode of each of the two or more first thin film transistors and a second gate electrode of the second thin film transistor are disposed at the same side of the common active region, and wherein a distance between the second gate electrode of the second thin film transistor and the common active region is greater than a distance between the first gate electrode of each of the two or more first thin film transistors and the common active region.

The common active region may include a source region, a drain region and a channel region, and the channel region may be configured between the source region and the drain region.

The first gate electrodes of the two or more first thin film transistors may be spaced apart from each other by a predetermined distance, and the second gate electrode of the second thin film transistor may be disposed above each of the first gate electrodes to cover the predetermined distance.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A thin film transistor, comprising:
a semiconductor layer;
a first insulating layer on the semiconductor layer;
two or more first gate electrodes on the first insulating layer and separated from each other;
a second insulating layer on the two or more first gate electrodes;
a source electrode and a drain electrode on the second insulating layer, the source electrode and the drain electrode respectively electrically connected to a source region and a drain region of the semiconductor layer; and
a second gate electrode above the two or more first gate electrodes,
wherein a channel region is between the source region and the drain region.

2. The thin film transistor of claim 1, wherein the second gate electrode is on the second insulating layer between the source electrode and the drain electrode.

3. The thin film transistor of claim 1, wherein the two or more first gate electrodes are spaced apart from each other by a predetermined distance, and the second gate electrode is above the two or more first gate electrodes such that the predetermined distance is covered by the second gate electrode.

4. The thin film transistor of claim 1, wherein the semiconductor layer outside the two or more first gate electrodes constitutes the source region and the drain region, and the semiconductor layer below the two or more first gate electrodes and the second gate electrode constitutes the channel region.

5. The thin film transistor of claim 4, wherein an outer edge of one first gate electrode from the two or more first gate electrodes and a boundary between the source region and the channel region are self-aligned and an outer edge of another first gate electrode from the two or more first gate electrodes and a boundary between the drain region and the channel region are self-aligned.

6. The thin film transistor of claim 1, wherein the second gate electrode overlaps at least a portion of the two or more first gate electrodes.

7. The thin film transistor of claim 1, wherein the second gate electrode is electrically connected to the two or more first gate electrodes through a contact hole.

8. The thin film transistor of claim 1, wherein the second insulating layer has a thickness that is greater than a thickness of the first insulating layer.

9. An electroluminescent display device, comprising:
a first thin film transistor and a second thin film transistor on a substrate; and
a light emitting element above the first thin film transistor and the second thin film transistor,
wherein the first thin film transistor includes:
a first semiconductor layer on the substrate,
a gate insulating layer on the first semiconductor layer,
two or more first gate electrodes on the gate insulating layer and separated from each other,
an interlayer insulating layer on the two or more first gate electrodes,
a first source electrode and a first drain electrode on the interlayer insulating layer, the first source electrode and the first drain electrode respectively electrically connected to a source region and a drain region of the first semiconductor layer, and
a second gate electrode disposed above the two or more first gate electrodes,
wherein a channel region is between the source region and the drain region, and
wherein the second thin film transistor includes:
a second semiconductor layer on the substrate,
the gate insulating layer on the second semiconductor layer,
a third gate electrode on the gate insulating layer,
the interlayer insulating layer on the third gate electrode, and
a second source electrode and a second drain electrode on the interlayer insulating layer.

10. The electroluminescent display device of claim 9, further comprising:
a first light blocking layer on the substrate;
a first buffer layer on the first light blocking layer;
a second light blocking layer on the first buffer layer; and
a second buffer layer on the second light blocking layer.

11. The electroluminescent display device of claim 10, wherein the first light blocking layer and the second light blocking layer are under the first thin film transistor.

12. The electroluminescent display device of claim 9, wherein the second gate electrode is on the interlayer insulating layer between the first source electrode and the first drain electrode of the first thin film transistor.

13. The electroluminescent display device of claim 9, wherein the two or more first gate electrodes are spaced apart from each other by a predetermined distance, and the second gate electrode is above the two or more first gate electrodes such that the predetermined distance is covered by the second gate electrode.

14. The electroluminescent display device of claim 9, wherein the second gate electrode overlaps at least a portion of the two or more first gate electrodes.

15. The electroluminescent display device of claim 9, wherein the second gate electrode is electrically connected to the two or more first gate electrodes through a contact hole.

16. The electroluminescent display device of claim 9, wherein the interlayer insulating layer has a thickness that is greater than a thickness of the gate insulating layer.

17. The electroluminescent display device of claim 9, wherein the first thin film transistor includes a driving transistor.

18. The electroluminescent display device of claim 9, wherein the second thin film transistor includes a switching transistor, a scan transistor, a sensing transistor, and a gate in panel transistor.

19. A driving transistor, comprising:
two or more first thin film transistors and a second thin film transistor that are in series with each other,
wherein each of the two or more first thin film transistors and the second thin film transistor have a common active region,
wherein a first gate electrode of each of the two or more first thin film transistors and a second gate electrode of the second thin film transistor are at a same side of the common active region, and
wherein a distance between the second gate electrode of the second thin film transistor and the common active region is greater than a distance between the first gate electrode of each of the two or more first thin film transistors and the common active region.

20. The driving transistor of claim 19, wherein the common active region includes a source region, a drain region and a channel region, and wherein the channel region is between the source region and the drain region.

21. The driving transistor of claim 19, wherein first gate electrodes of the two or more first thin film transistors are spaced apart from each other by a predetermined distance, and the second gate electrode of the second thin film transistor is above each of the first gate electrodes such that the predetermined distance is covered by the second gate electrode.
